(19) United States
(12) Patent Application Publication
(10) Pub. No.: US 2026/0073107 A1
(43) Pub. Date: Mar. 12, 2026

(54) METHOD OF ANALYZING SEMICONDUCTOR CIRCUIT, ANALYSIS SYSTEM PERFORMING THE SAME, AND METHOD OF DESIGNING SEMICONDUCTOR DEVICE USING THE SAME

(71) Applicant: Samsung Electronics Co., Ltd., Suwon-si (KR)

(72) Inventors: Jeongyoon Lee, Suwon-si (KR); Youngwook Kim, Suwon-si (KR); Seunghwan Lee, Suwon-si (KR); Kyeongrok Jo, Suwon-si (KR)

(21) Appl. No.: 19/269,933

(22) Filed: Jul. 15, 2025

(30) Foreign Application Priority Data
Sep. 9, 2024 (KR) 10-2024-0122357

(51) Int. Cl. G06F 30/327; G06F 30/347

(52) U.S. Cl. CPC G06F 30/327; G06F 30/347

(57) ABSTRACT

In an example method of analyzing a semiconductor circuit, a netlist of the semiconductor circuit is received. The semiconductor circuit includes a plurality of transistors and a plurality of optional instances. A first circuit graph is generated based on the netlist of the semiconductor circuit. The first circuit graph includes a plurality of vertices and a plurality of edges. A second circuit graph is generated based on the first circuit graph. The second circuit graph is a circuit graph in which the plurality of optional instances are simplified from the first circuit graph. A final circuit graph is generated based on the second circuit graph. The final circuit graph is a circuit graph in which at least one transistor of the plurality of transistors is simplified from the second circuit graph.

### CROSS-REFERENCE TO RELATED APPLICATION

This application claims priority under 35 USC § 119 to Korean Patent Application No. 10-2024-0122357 filed on Sep. 9, 2024, in the Korean Intellectual Property Office (KIPO), the contents of which are herein incorporated by reference in their entirety.

### BACKGROUND

A semiconductor device may be manufactured by patterning devices and mutual connections thereof on a substrate such as a semiconductor wafer. A semiconductor device may be manufactured through a process in which a designer designs an integrated circuit using at least one of various tools, which enables various circuit components to be placed to interact with each other and to be connected to each other.

Example methods for automating the design may include storing a plurality of semiconductor circuits in a database and searching for the database to find a semiconductor circuit having the same structure as the semiconductor circuit to be actually applied.

### SUMMARY

The present disclosure relates to a method of analyzing a semiconductor circuit capable of efficiently simplifying a structure of the semiconductor circuit for relatively fast search during a design for a semiconductor device, an analysis system performing the method of analyzing the semiconductor circuit, and a method of designing a semiconductor device using the method of analyzing the semiconductor circuit.

In some implementations, in a method of analyzing a semiconductor circuit, the method is performed by executing program code by at least one processor, and the program code is stored in a non-transitory computer readable medium. A netlist of the semiconductor circuit including a plurality of transistors and a plurality of optional instances is received. A first circuit graph is generated based on the netlist of the semiconductor circuit. The first circuit graph includes a plurality of vertices and a plurality of edges. A second circuit graph is generated based on the first circuit graph. The second circuit graph is a circuit graph in which the plurality of optional instances are simplified from the first circuit graph. A final circuit graph is generated based on the second circuit graph. The final circuit graph is a circuit graph in which at least one of the plurality of transistors is simplified from the second circuit graph.

In some implementations, an analysis system includes at least one processor and a non-transitory computer readable medium. The non-transitory computer readable medium stores program code executed by the at least one processor to analyze a semiconductor circuit including a plurality of transistors and a plurality of option instances. The at least one processor, by executing the program code, receives a netlist of the semiconductor circuit, generates a first circuit graph based on the netlist of the semiconductor circuit, generates a second circuit graph based on the first circuit graph, and generate a final circuit graph based on the second circuit graph. The first circuit graph includes a plurality of vertices and a plurality of edges. The second circuit graph is a circuit graph in which the plurality of optional instances are simplified from the first circuit graph. The final circuit graph is a circuit graph in which at least one of the plurality of transistors is simplified from the second circuit graph.

In some implementations, in a method of designing a semiconductor device including a plurality of semiconductor circuits, each of the plurality of semiconductor circuits is analyzed by executing program code by at least one processor. The program code is stored in a non-transitory computer readable medium. A design for the semiconductor device is performed based on a result of analyzing each of the plurality of semiconductor circuits. Each of the plurality of semiconductor circuits includes a plurality of transistors and a plurality of optional instances. When analyzing each of the plurality of semiconductor circuits, a netlist of a first semiconductor circuit among the plurality of semiconductor circuits is received. A first circuit graph is generated based on the netlist of the first semiconductor circuit. The first circuit graph includes a plurality of vertices and a plurality of edges. A second circuit graph is generated based on the first circuit graph. The second circuit graph is a circuit graph in which the plurality of optional instances are simplified from the first circuit graph. A final circuit graph is generated based on the second circuit graph. The final circuit graph is a circuit graph in which at least one of the plurality of transistors is simplified from the second circuit graph.

In some implementations, in the method of analyzing the semiconductor circuit, the analysis system and the method of designing the semiconductor device, portions corresponding to the plurality of optional instances in the circuit graph and portions corresponding to at least one of the plurality of transistors in the circuit graph may be simplified and/or omitted. Therefore, as compared with a conventional circuit graph, a simplified circuit graph with a less complex structure may be obtained, and the database may be searched using the simplified circuit graph. Accordingly, relatively faster search may be performed using relatively fewer resources (e.g., memory), and the design automation may be implemented efficiently.

### BRIEF DESCRIPTION OF THE DRAWINGS

Illustrative, non-limiting example implementations will be more clearly understood from the following detailed description taken in conjunction with the accompanying drawings.

FIG. 1 is a flowchart illustrating an example of a method of analyzing a semiconductor circuit.

FIGS. 2 and 3 are block diagrams illustrating an example of an analysis system.

FIG. 4 is a flowchart illustrating an example of generating a first circuit graph in FIG. 1.

FIGS. 5A and 5B are diagrams for describing an example of an operation of FIG. 4.

FIG. 6 is a flowchart illustrating an example of generating a second circuit graph in FIG. 1.

FIG. 7 is a diagram for describing an example of an operation of FIG. 6.

FIG. 8 is a flowchart illustrating an example of generating a final circuit graph in FIG. 1.

FIGS. 9A, 9B, and 9C are diagrams for describing an example of an operation of FIG. 8.

FIG. 10 is a flowchart illustrating an example of generating a final circuit graph in FIG. 1.

FIGS. 11A and 11B are diagrams for describing an example of an operation of FIG. 10.

FIG. 12 is a flowchart illustrating an example of generating a final circuit graph in FIG. 1.

FIGS. 13A, 13B, 13C, and 13D are diagrams for describing an example of an operation of FIG. 12.

FIGS. 14A, 14B, 14C, and 14D are diagrams for describing an example of a method of analyzing a semiconductor circuit.

FIG. 15 is a flowchart illustrating an example of a method of analyzing a semiconductor circuit.

FIGS. 16A, 16B, 17A, 17B, 18A, 18B, and 18C are diagrams for describing an example of a method of analyzing a semiconductor circuit.

FIG. 19 is a flowchart illustrating an example of a method of designing a semiconductor device.

FIG. 20 is a flowchart illustrating an example of a method of manufacturing a semiconductor device.

### DETAILED DESCRIPTION

Various example implementations will be described more fully with reference to the accompanying drawings. The present disclosure may, however, be implemented in many different forms and should not be construed as limited to the implementations set forth herein. Like reference numerals refer to like elements throughout this application.

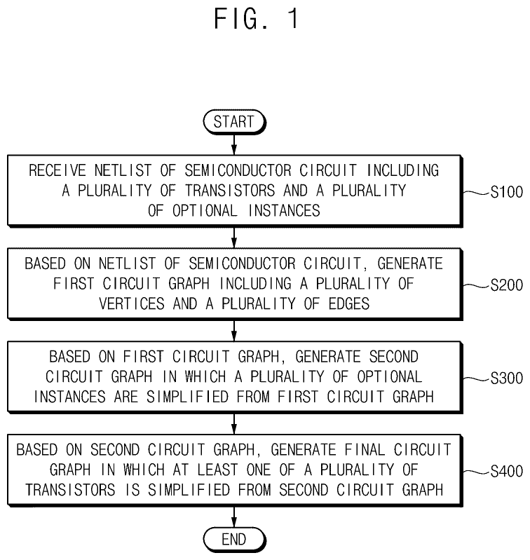

FIG. 1 is a flowchart illustrating an example of a method of analyzing a semiconductor circuit.

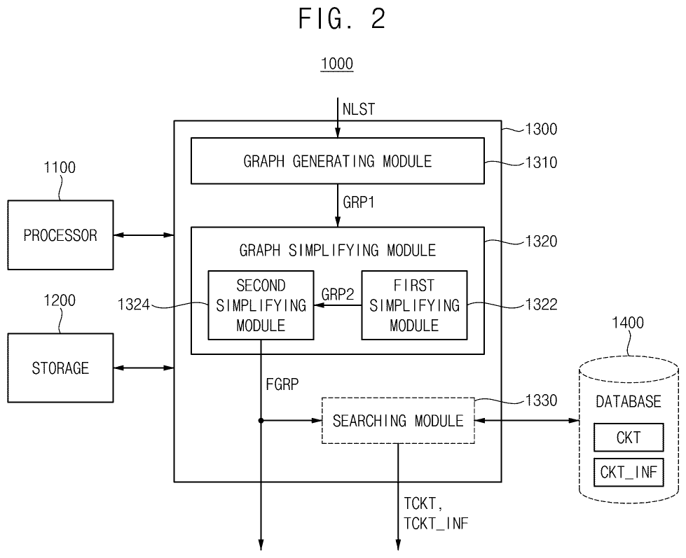

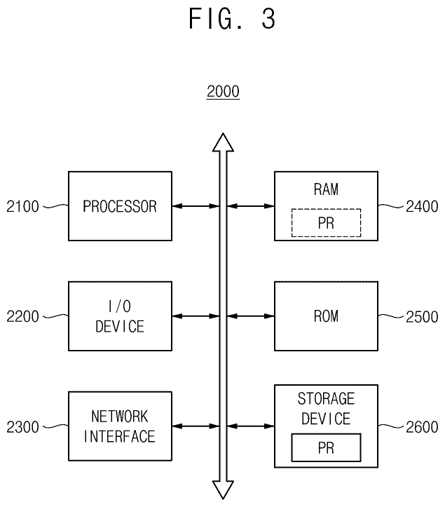

Referring to FIG. 1, a method of analyzing a semiconductor circuit may be performed during a design process or phase of a semiconductor device including the semiconductor circuit. In addition, the method of analyzing the semiconductor circuit may be performed on an analysis system (or tool) for the semiconductor circuit, and/or may be performed on a design system (or tool) for the semiconductor device. For example, the design system may be a semiconductor design automation system. For example, the analysis system and/or the design system may be or may include a program including a plurality of instructions executed by a processor. The analysis system will be described with reference to FIGS. 2 and 3.

In the method of analyzing the semiconductor circuit, a netlist of the semiconductor circuit is received (operation S100). The semiconductor circuit includes a plurality of transistors and a plurality of optional instances. For example, the netlist may include or may represent a structure (or configuration) of the semiconductor circuit.

In some implementations, the netlist may be data generated from an abstract form with respect to behavior of the semiconductor circuit. For example, the netlist may be defined in a register transfer level (RTL) through synthesis. For example, the netlist may be generated by synthesizing the semiconductor circuit defined by a hardware description language (HDL) such as VHSIC hardware description language (VHDL) or Verilog. However, implementations are not limited thereto, and information associated with or related to the structure of the semiconductor circuit may be received in various manners, such as a bitstream other than the netlist.

Among elements or components included in the semiconductor circuit, the plurality of transistors may be active elements for an operation of the semiconductor circuit, and the plurality of optional instances may be elements for selectively changing the structure of the semiconductor circuit. For example, each of the plurality of optional instances may be configured to electrically connect two adjacent nodes with each other or electrically disconnect two adjacent nodes from each other. For example, each of the plurality of optional instances may be a metal optional instance. In other words, each of the plurality of optional instances may correspond to a metal wiring, and two adjacent nodes may be electrically connected with each other or electrically disconnected from each other by forming or omitting the metal wiring. However, implementations are not limited thereto, and each of the plurality of optional instances may be implemented in various manners, such as a via optional instance corresponding to a via other than the metal optional instance.

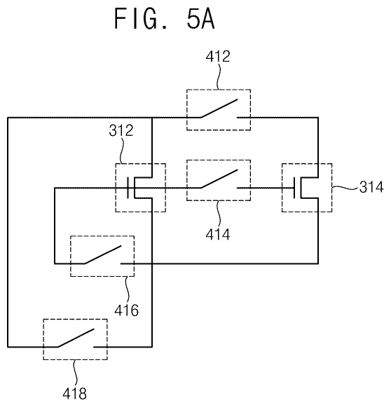

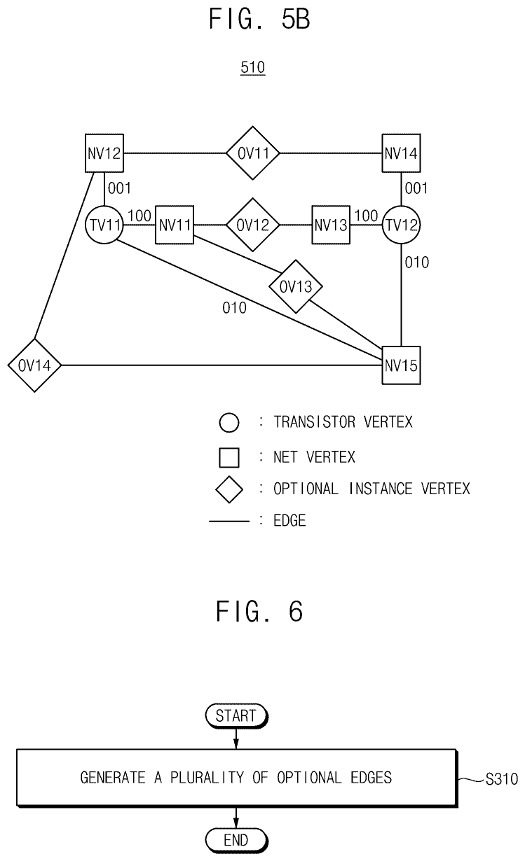

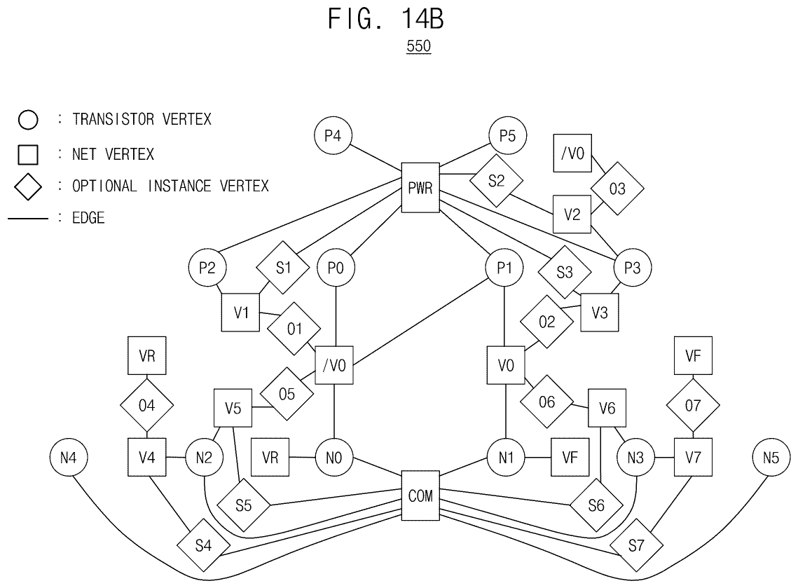

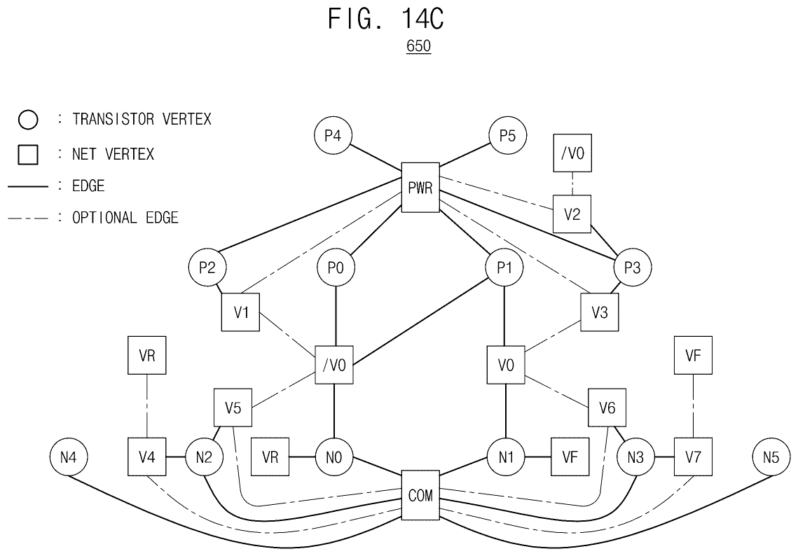

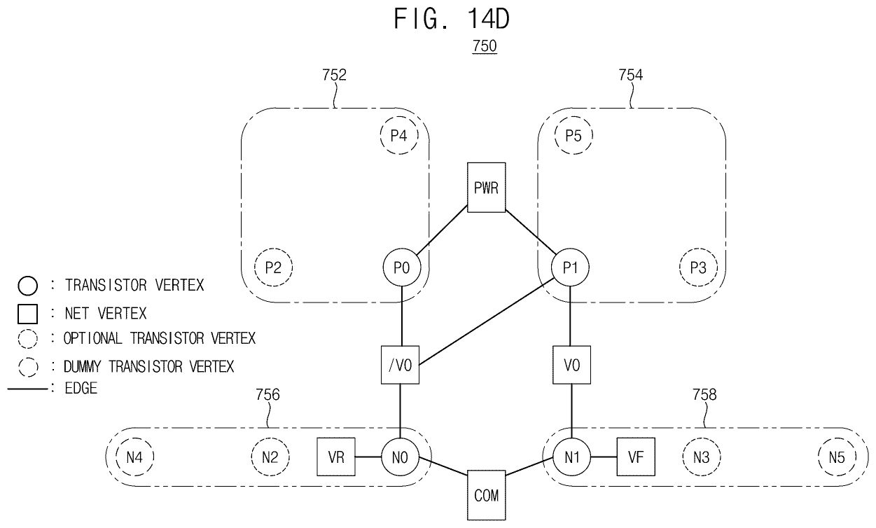

Examples of the semiconductor circuit will be described with reference to FIGS. 5A and 14A.

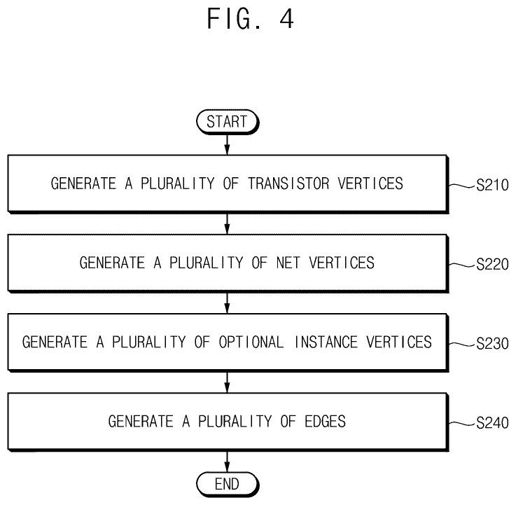

A first circuit graph is generated or formed based on the netlist of the semiconductor circuit (operation S200). The first circuit graph includes a plurality of vertices and a plurality of edges. For example, the elements included in the semiconductor circuit and their connection relationships may be converted into the plurality of vertices and the plurality of edges. Operation S200 will be described with reference to FIG. 4.

A second circuit graph is generated or formed based on the first circuit graph (operation S300). The second circuit is a circuit graph in which the plurality of optional instances are simplified from the first circuit graph. For example, among the plurality of vertices and the plurality of edges that are included in the first circuit graph, portions (or parts) corresponding to the plurality of optional instances may be simplified and/or omitted. Operation S300 will be described with reference to FIG. 6.

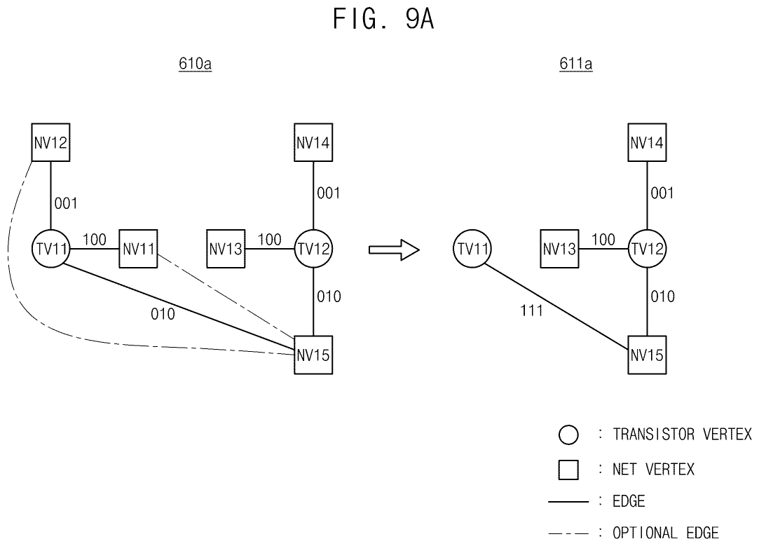

A final circuit graph is generated or formed based on the second circuit graph (operation S400). The final circuit graph is a circuit graph in which at least one of the plurality of transistors is simplified from the second circuit graph. For example, among the plurality of vertices and the plurality of edges that are included in the second circuit graph, portions corresponding to at least one of the plurality of transistors may be simplified and/or omitted. Operation S400 will be described later with reference to FIGS. 8, 10 and 12.

In some implementations, portions corresponding to at least one dummy transistor among the plurality of transistors may be simplified and/or omitted. In some implementations, portions corresponding to at least one optional transistor among the plurality of transistors may be simplified and/or omitted. In some implementations, portions corresponding to at least one parallel transistor among the plurality of transistors may be simplified and/or omitted.

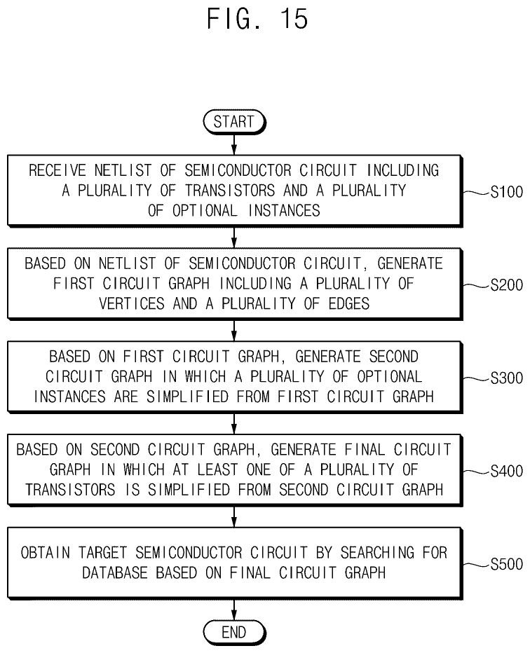

In some implementations, as will be described with reference to FIG. 15, an operation of searching for a database using the final circuit graph may be additionally performed after operation S400.

When designing a semiconductor circuit, various types of optional instances may be used to easily change a routing, e.g., electrical connections of elements included in the semiconductor circuit. In addition, to automate the design, a method of storing a plurality of semiconductor circuits in a database and searching for the database to find a semiconductor circuit having the same structure as the semiconductor circuit to be actually applied may be used. For example, a semiconductor circuit may be converted into a circuit graph, and the circuit graph may be used to search for a semiconductor circuit having the same structure.

When converting a semiconductor circuit including optional instances into a circuit graph, the structural variability due to optional instances may not be predicted, so the database should be implemented by considering all possible cases. In the real design process, various derivation (or modified) netlists of a specific semiconductor circuit should be designed based on a reference netlist of the specific semiconductor circuit, and thus there may be a problem that it is difficult to implement a database that included all of such structures.

In the method of analyzing the semiconductor circuit, portions corresponding to the plurality of optional instances in the circuit graph and portions corresponding to at least one of the plurality of transistors in the circuit graph may be simplified and/or omitted. Therefore, as compared with a conventional circuit graph, a simplified circuit graph with a less complex structure may be obtained, and the database may be searched using the simplified circuit graph. Accordingly, relatively faster search may be performed using relatively fewer resources (e.g., memory), and the design automation may be implemented efficiently.

FIGS. 2 and 3 are block diagrams illustrating an example of an analysis system.

Referring to FIG. 2, an analysis system 1000 for a semiconductor circuit includes a processor 1100, a storage device 1200 and an analysis module 1300.

Herein, the term “module” may indicate, but is not limited to, a software and/or hardware component, such as a field programmable gate array (FPGA) or an application specific integrated circuit (ASIC), which performs certain tasks. A module may be configured to reside in a tangible addressable storage medium and be configured to execute on one or more processors. For example, a “module” may include components such as software components, object-oriented software components, class components and task components, and processes, functions, Routines, segments of program code, drivers, firmware, microcode, circuitry, data, databases, data structures, tables, arrays, and variables. A “module” may be divided into a plurality of “modules” that perform detailed functions.

The processor 1100 may control an operation of the analysis system 1000, and may be used when the analysis system 1000 performs computations or calculations. For example, the processor 1100 may include a microprocessor, an application processor (AP), a central processing unit (CPU), a digital signal processor (DSP), a graphic processing unit (GPU), a neural processing unit (NPU), or the like. In FIG. 2, only one processor 1100 is illustrated, but implementations are not limited thereto. For example, a plurality of processors may be included in the analysis system 1000. In addition, the processor 1100 may include cache memories to increase computation capacity.

The storage device 1200 may store data used for the operation of the analysis system 1000. In some implementations, the storage device 1200 may include any non-transitory computer-readable storage medium used to provide commands and/or data to a computer. For example, the non-transitory computer-readable storage medium may include a volatile memory such as a static random access memory (SRAM), a dynamic random access memory (DRAM), or the like, and a nonvolatile memory such as a flash memory, a magnetic random access memory (MRAM), a phase-change random access memory (PRAM), a resistive random access memory (RRAM), or the like. The non-transitory computer-readable storage medium may be inserted into the computer, may be integrated in the computer, or may be coupled to the computer through a communication medium such as a network and/or a wireless link.

The analysis module 1300 may perform an analysis on a semiconductor circuit using the processor 1100. The analysis module 1300 may include a graph generating module 1310 and a graph simplifying module 1320, and may further include a searching module 1330. The graph simplifying module 1320 may include a first simplifying module 1322 and a second simplifying module 1324.

The graph generating module 1310 may receive a netlist NLST of the semiconductor circuit that includes a plurality of transistors and a plurality of optional instances, and may generate a first circuit graph GRP1 based on the netlist NLST. The graph simplifying module 1320 may perform a simplification operation on the first circuit graph GRP1. The first simplifying module 1322 may generate a second circuit graph GRP2 in which the plurality of optional instances are simplified based on the first circuit graph GRP1. The second simplifying module 1324 may generate a final circuit graph FGRP in which at least one of the plurality of transistors is simplified based on the second circuit graph GRP2.

In other words, the analysis module 1300 may perform the method of analyzing the semiconductor circuit described with reference to FIG. 1. For example, the graph generating module 1310 may perform operations S100 and S200 in FIG. 1, the first simplifying module 1322 may perform operation S300 in FIG. 1, and the second simplifying module 1324 may perform operation S400 in FIG. 1.

The searching module 1330 may perform a search operation on a database 1400 using the final circuit graph FGRP. For example, the database 1400 may be disposed or located outside the analysis system 1000, and may store a plurality of semiconductor circuits CKT and circuit information CKT_INF associated with or related to the plurality of semiconductor circuits CKT. The searching module 1330 may obtain and output a target semiconductor circuit TCKT that is matched with the semiconductor circuit corresponding to the final circuit graph FGRP among the plurality of semiconductor circuits CKT, and target circuit information TCKT_INF associated with the target semiconductor circuit TCKT. For example, the target semiconductor circuit TCKT and the target circuit information TCKT_INF may be provided to a design system, and may be used to design a semiconductor device including the semiconductor circuit.

In other words, the analysis module 1300 may perform a method of analyzing a semiconductor circuit, which will be described with reference to FIG. 15. For example, the searching module 1330 may perform operation S500 in FIG. 15.

In some implementations, the graph generating module 1310, the graph simplifying module 1320 and the searching module 1330 may be implemented as instructions or program code that may be executed by the processor 1100. For example, the instructions or program code of the graph generating module 1310, the graph simplifying module 1320 and the searching module 1330 may be stored in computer readable medium. For example, the processor 1100 may load the instructions or program code to a working memory (e.g., a DRAM, etc.).

In other implementations, the processor 1100 may be manufactured to efficiently execute instructions or program code included in the graph generating module 1310, the graph simplifying module 1320 and the searching module 1330. For example, the processor 1100 may efficiently execute the instructions or program code from various AI modules and/or machine learning modules. For example, the processor 1100 may receive information corresponding to the graph generating module 1310, the graph simplifying module 1320 and the searching module 1330 to operate the graph generating module 1310, the graph simplifying module 1320 and the searching module 1330.

In some implementations, at least two of the graph generating module 1310, the graph simplifying module 1320 and the searching module 1330 may be implemented as a single integrated module. In other implementations, the graph generating module 1310, the graph simplifying module 1320 and the searching module 1330 may be implemented as separate and different modules.

Referring to FIG. 3, an analysis system 2000 for a semiconductor circuit includes a processor 2100, an input/output (I/O) device 2200, a network interface 2300, a random access memory (RAM) 2400, a read only memory (ROM) 2500 and/or a storage device 2600. FIG. 3 illustrates an example where all of the graph generating module 1310, the graph simplifying module 1320 and the searching module 1330 in FIG. 2 are implemented in software.

The analysis system 2000 may be a computing system. For example, the computing system may be a fixed computing system such as a desktop computer, a workstation or a server, or may be a portable computing system such as a laptop computer.

The processor 2100 may be substantially the same as the processor 1100 in FIG. 2. For example, the processor 2100 may include a core or a processor core for executing an arbitrary instruction set (for example, intel architecture-32 (IA-32), 64 bit extension IA-32, x86-64, PowerPC, Sparc, MIPS, ARM, IA-64, etc.). For example, the processor 2100 may access a memory (e.g., the RAM 2400 or the ROM 2500) through a bus, and may execute instructions stored in the RAM 2400 or the ROM 2500. As illustrated in FIG. 3, the RAM 2400 may store a program PR corresponding to the graph generating module 1310, the graph simplifying module 1320 and the searching module 1330 in FIG. 2 or at least some elements of the program PR, and the program PR may allow the processor 2100 to perform operations for analyzing the semiconductor circuit during a design process (e.g., operations S100, S200, S300, S400 and S500 in FIGS. 1 and 15).

In other words, the program PR may include a plurality of instructions and/or procedures executable by the processor 2100, and the plurality of instructions and/or procedures included in the program PR may allow the processor 2100 to perform the method of analyzing the semiconductor circuit. Each of the procedures may denote a series of instructions for performing a certain task. A procedure may be referred to as a function, a routine, a subroutine, or a subprogram. Each of the procedures may process data provided from the outside and/or data generated by another procedure.

In some implementations, the RAM 2400 may include a volatile memory such as a SRAM, a DRAM, or the like.

The storage device 2600 may store the program PR, and the program PR or at least some elements of the program PR may be loaded from the storage device 2600 to the RAM 2400 before being executed by the processor 2100. The storage device 2600 may store a file written in a program language, and the program PR generated by a compiler or the like or at least some elements of the program PR may be loaded to the RAM 2400.

The storage device 2600 may store data, which is to be processed by the processor 2100, or data obtained through processing by the processor 2100. The processor 2100 may process the data stored in the storage device 2600 to generate new data, based on the program PR and may store the generated data in the storage device 2600.

The I/O device 2200 may include an input device, such as a keyboard, a pointing device, or the like, and may include an output device such as a display device, a printer, or the like. For example, a user may trigger, through the I/O devices 2200, execution of the program PR by the processor 2100, and may provide or check various inputs, outputs and/or data, etc.

The network interface 2300 may provide access to a network outside the analysis system 2000. For example, the network may include a plurality of computing systems and communication links, and the communication links may include wired links, optical links, wireless links, or arbitrary other type links. Various inputs may be provided to the analysis system 2000 through the network interface 2300, and various outputs may be provided to another computing system through the network interface 2300.

In some implementations, the computer program code, the graph generating module 1310, the graph simplifying module 1320 and the searching module 1330 may be stored in a transitory or non-transitory computer readable medium. In some implementations, values resulting from the simulation performed by the processor or values obtained from arithmetic processing performed by the processor may be stored in a transitory or non-transitory computer readable medium. In some implementations, intermediate values during the simulation and/or various data generated by the simulation may be stored in a transitory or non-transitory computer readable medium. However, implementations are not limited thereto.

FIG. 4 is a flowchart illustrating an example of generating a first circuit graph in FIG. 1. FIGS. 5A and 5B are diagrams for describing an example of an operation of FIG. 4.

Referring to FIGS. 1 and 4, when generating the first circuit graph (operation S200), a plurality of transistor vertices may be generated based on the plurality of transistors included in the semiconductor circuit (operation S210). For example, each transistor may be converted into a transistor vertex, and one transistor vertex may correspond to one transistor. To distinguish from an optional transistor vertex which will be described with reference to FIG. 8, a dummy transistor vertex which will be described with reference to FIG. 10, and a parallel transistor vertex which will be described with reference to FIG. 12, the transistor vertex generated by operation S210 may be referred to as a main transistor vertex or a normal transistor vertex.

A plurality of net vertices may be generated based on electrodes of the plurality of transistors (operation S220). For example, each node connected to each electrode (e.g., gate electrode, source electrode and drain electrode) of each transistor may be converted into a net vertex, and one net vertex may correspond to one node connected to one electrode of one transistor. For example, each voltage provided to each electrode of a transistor may be converted into a net vertex, and one net vertex may correspond to one voltage provided to one electrode of one transistor.

A plurality of optional instance vertices may be generated based on the plurality of optional instances (operation S230). For example, each optional instance may be converted into an optional instance vertex, and one optional instance vertex may correspond to one optional instance.

A plurality of edges, which are configured to connect the plurality of transistor vertices, the plurality of net vertices and the plurality of optional instance vertices with each other, may be generated (operation S240). For example, each edge may correspond to an electrical connection between two vertices. To distinguish from an optional edge which will be described with reference to FIG. 6, the edge generated by operation S240 may be referred to as a main edge or a normal edge.

Referring to FIGS. 5A and 5B, an example of a netlist 210 of a specific semiconductor circuit (or at least a part thereof) is illustrated, and an example of a first circuit graph 510 obtained based on the netlist 210 is illustrated.

The netlist 210 of the semiconductor circuit may include transistors 312 and 314 and optional instances 412, 414, 416 and 418. For example, each of the transistors 312 and 314 may be an n-type metal oxide semiconductor (NMOS) transistor.

The optional instance 412 may be configured to electrically connect or disconnect drain electrodes of the transistors 312 and 314 with or from each other. For example, when the optional instance 412 is implemented in a short state, e.g., when a metal wiring corresponding to the optional instance 412 is formed, the drain electrodes of the transistors 312 and 314 may be electrically connected with each other. For example, when the optional instance 412 is implemented in an open state, e.g., when the metal wiring corresponding to the optional instance 412 is omitted, the drain electrodes of the transistors 312 and 314 may be electrically disconnected from each other.

Similarly, the optional instance 414 may be configured to electrically connect or disconnect gate electrodes of the transistors 312 and 314 with or from each other, the optional instance 416 may be configured to electrically connect or disconnect the gate electrode of the transistor 312 with or from source electrodes of the transistors 312 and 314, and the optional instance 418 may be configured to electrically connect or disconnect the drain and source electrodes of the transistor 312 with or from each other.

The first circuit graph 510 may include transistor vertices TV11 and TV12, net vertices NV11, NV12, NV13, NV14 and NV15, optional instance vertices OV11, OV12, OV13 and OV14, and edges.

For example, when operation S210 in FIG. 4 is performed on the netlist 210 of the semiconductor circuit, the transistor 312 may be converted into the transistor vertex TV11, and the transistor 314 may be converted into the transistor vertex TV12.

For example, when operation S220 in FIG. 4 is performed on the netlist 210 of the semiconductor circuit, a node connected to the gate electrode of the transistor 312 may be converted into the net vertex NV11, a node connected to the drain electrode of the transistor 312 may be converted to the net vertex NV12, a node connected to the gate electrode of the transistor 314 may be converted into the net vertex NV13, a node connected to the drain electrode of the transistor 314 may be converted to the net vertex NV14, and a node connected to the source electrodes of the transistors 312 and 314 may be converted to the net vertex NV15.

For example, when operation S230 in FIG. 4 is performed on the netlist 210 of the semiconductor circuit, the optional instance 412 may be converted into the optional instance vertex OV11, the optional instance 414 may be converted into the optional instance vertex OV12, the optional instance 416 may be converted into the optional instance vertex OV13, and the optional instance 418 may be converted into the optional instance vertex OV14.

For example, when operation S240 in FIG. 4 is performed on the netlist 210 of the semiconductor circuit, the edges configured to connect the transistor vertices TV11 and TV12, the net vertices NV11, NV12, NV13, NV14 and NV15, and the optional instance vertices OV11, OV12, OV13 and OV14 with each other may be obtained.

In some implementations, a three-bit label written on each edge may represent or indicate a connection relationship between each edge and at least one electrode of each transistor. For example, among three bits of the label, a most significant bit (MSB) may represent a connection to a gate electrode. For example, it may represent that an edge is connected to a gate electrode when the MSB is ‘l’, and it may represent that the edge is not connected to the gate electrode when the MSB is ‘0’. For example, among three bits of the label, a central significant bit (CSB) may represent a connection to a source electrode. For example, it may represent that an edge is connected to a source electrode when the CSB is ‘l’, and it may represent that the edge is not connected to the source electrode when the CSB is ‘0’. For example, among three bits of the label, a least significant bit (LSB) may represent a connection to a drain electrode. For example, it may represent that an edge is connected to a drain electrode when the LSB is ‘l’, and it may represent that the edge is not connected to the drain electrode when the LSB is ‘0’.

For example, a label ‘100’ written on an edge between the transistor vertex TV11 and the net vertex NV11 may represent that the edge is connected to the gate electrode of the transistor 312 and is not connected to the source and drain electrodes of the transistor 312. For example, a label ‘001’ written on an edge between the transistor vertex TV11 and the net vertex NV12 may represent that the edge is connected to the drain electrode of the transistor 312 and is not connected to the gate and source electrodes of the transistor 312. For example, a label ‘010’ written on an edge between the transistor vertex TV11 and the net vertex NV15 may represent that the edge is connected to the source electrode of the transistor 312 and is not connected to the gate and drain electrodes of the transistor 312.

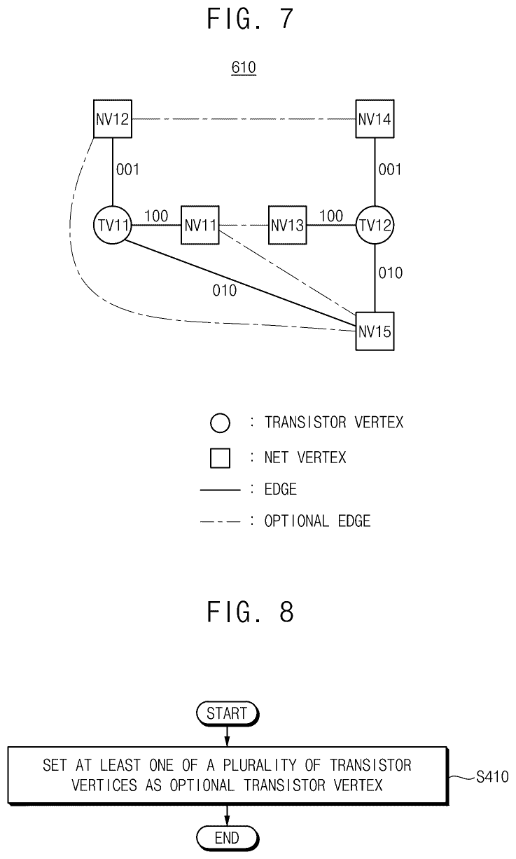

FIG. 6 is a flowchart illustrating an example of generating a second circuit graph in FIG. 1. FIG. 7 is a diagram for describing an example of an operation of FIG. 6.

Referring to FIGS. 1 and 6, when generating the second circuit graph (operation S300), a plurality of optional edges may be generated based on the plurality of optional instance vertices and at least some of the plurality of edges (operation S310). For example, the circuit graph may be simplified by converting each optional instance vertex and at least one edge directly connected thereto into an optional edge.

Referring to FIG. 7, an example of a second circuit graph 610 obtained based on the first circuit graph 510 of FIG. 5B is illustrated.

For example, when operation S310 in FIG. 6 is performed on the first circuit graph 510, the optional instance vertex OV11 and the edges connecting the optional instance vertex OV11 with the net vertices NV12 and NV14 in FIG. 5B may be converted into one optional edge, the optional instance vertex OV12 and the edges connecting the optional instance vertex OV12 with the net vertices NV11 and NV13 in FIG. 5B may be converted into one optional edge, the optional instance vertex OV13 and the edges connecting the optional instance vertex OV13 with the net vertices NV11 and NV15 in FIG. 5B may be converted into one optional edge, and the optional instance vertex OV14 and the edges connecting the optional instance vertex OV14 with the net vertices NV12 and NV15 in FIG. 5B may be converted into one optional edge.

Therefore, as compared with the first circuit graph 510 of FIG. 5B, the second circuit graph 610 of FIG. 7 may have the simple structure, and the complexity of the circuit graph may be reduced by performing operation S310 in FIG. 6.

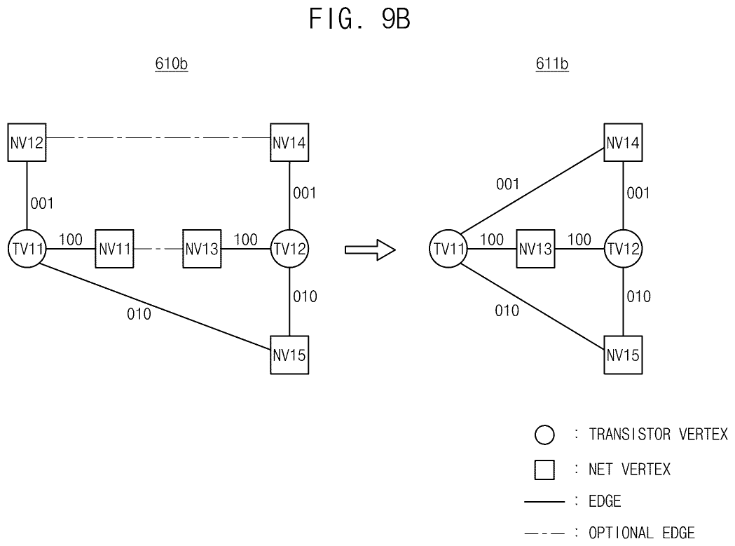

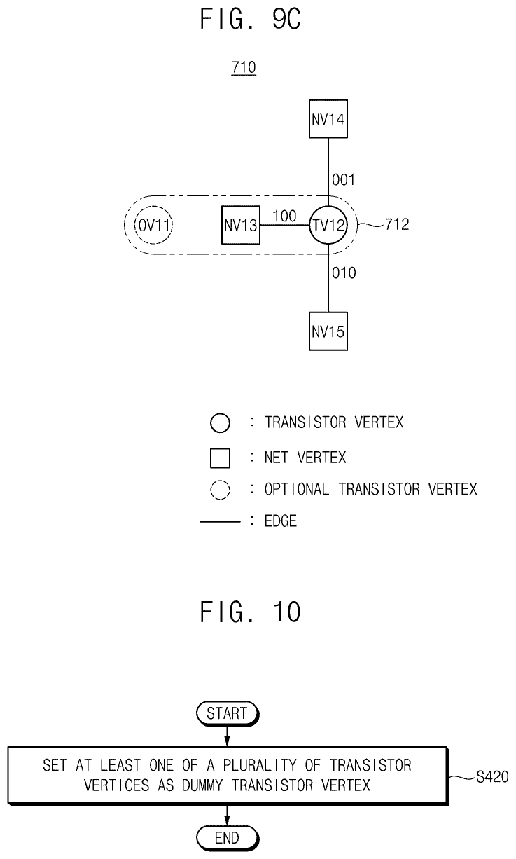

FIG. 8 is a flowchart illustrating an example of generating a final circuit graph in FIG. 1. FIGS. 9A, 9B, and 9C are diagrams for describing an example of an operation of FIG. 8.

Referring to FIGS. 1 and 8, when generating the final circuit graph (operation S400), at least one of the plurality of transistor vertices may be set as an optional transistor vertex (operation S410). For example, when a specific transistor is implemented to have two different structures and/or connections by optional instances, e.g., when the specific transistor is an optional transistor, a circuit graph including the specific transistor may be simplified by converting a transistor vertex corresponding to the specific transistor into an optional transistor vertex.

Referring to FIGS. 9A, 9B and 9C, an example where the transistor 312 in FIG. 5A that corresponds to the transistor vertex TV11 included in the second circuit graph 610 of FIG. 7 is determined as an optional transistor is illustrated, and an example of a final circuit graph 710 obtained based on the second circuit graph 610 is illustrated.

A circuit graph 610a on the left side of FIG. 9A may represent an example where only the optional edge between the net vertices N11 and N15 and the optional edge between the net vertices N12 and N15 among the four optional edges included in the second circuit graph 610 of FIG. 7 are formed. In this example, the gate electrode, the source electrode and the drain electrode of the transistor 312 in FIG. 5A corresponding to the transistor vertex TV11 may be electrically connected with each other.

A circuit graph 611a on the right side of FIG. 9A may represent an equivalent circuit graph to the circuit graph 610a on the left side of FIG. 9A. In the circuit graph 611a, the net vertices N11 and N12 and the edges related thereto may be omitted, only the edge between the transistor vertex TV11 and the net vertex N15 may be remained. A label ‘111’ written on the edge between the transistor vertex TV11 and the net vertex N15 may represent that the edge is connected to all of the gate, source and drain electrodes of the transistor 312 in FIG. 5A corresponding to the transistor vertex TV11.

When all of gate, source and drain electrodes of a transistor corresponding to one transistor vertex are connected to one net vertex as illustrated in FIG. 9A, such transistor may be implemented as a dummy transistor.

A circuit graph 610b on the left side of FIG. 9B may represent an example where only the optional edge between the net vertices N12 and N14 and the optional edge between the net vertices N11 and N13 among the four optional edges included in the second circuit graph 610 of FIG. 7 are formed. In this example, the gate electrode, the source electrode and the drain electrode of the transistor 312 in FIG. 5A corresponding to the transistor vertex TV11 may be electrically connected with the gate electrode, the source electrode and the drain electrode of the transistor 314 in FIG. 5A corresponding to the transistor vertex TV12, respectively. In other words, the transistor 312 and 314 in FIG. 5A may be connected identically and may operate identically.

A circuit graph 611b on the right side of FIG. 9A may represent an equivalent circuit graph to the circuit graph 610b on the left side of FIG. 9A. In the circuit graph 611b, the net vertices N11 and N12 and the edges related thereto may be omitted, the edge between the transistor vertex TV11 and the net vertex N15 may be remained, and edges between the transistor vertex TV11 and the net vertices N13 and N14 may be added.

When gate, source and drain electrodes of two different transistors corresponding to two transistor vertices have the same connection structure as illustrated in FIG. 9B, such transistors may be implemented as parallel transistors.

As described above, the connection of the transistor vertex TV11 may be changed depending on the plurality of optional edges, e.g., depending on which of the four optional edges included in the second circuit graph 610 of FIG. 7 are formed and omitted. For example, as illustrated in FIG. 9A, all of the gate electrode, the source electrode and the drain electrode of the transistor 312 in FIG. 5A corresponding to the transistor vertex TV11 may be connected to the same net vertex NV15, and the transistor 312 in FIG. 5A corresponding to the transistor vertex TV11 can be implemented as a dummy transistor. For example, as illustrated in FIG. 9B, the connection of the transistor vertex TV11 and the connection of the transistor vertex TV12 may be identical to each other or may correspond to each other, and the transistor 312 in FIG. 5A corresponding to the transistor vertex TV11 may be implemented as a parallel transistor of the transistor 314 in FIG. 5A corresponding to the transistor vertex TV12. In other words, the transistor 312 in FIG. 5A corresponding to the transistor vertex TV11 may be a dummy transistor or a parallel transistor, and thus may be defined as an optional transistor.

Therefore, when operation S410 in FIG. 8 is performed on the second circuit graph 610, the transistor vertex TV11 may be set as an optional transistor vertex OV11, the edges related to the transistor vertex TV11 may be omitted, and the final circuit graph 710 may be obtained as illustrated in FIG. 9C.

In some implementations, the optional transistor vertex OV11 may be omitted from the final circuit graph 710. In other words, the final circuit graph 710 may not directly include the optional transistor vertex OV11. For example, the final circuit graph 710 may have a 4V-3E structure including four vertices TV12, NV13, NV14 and NV15 and three edges.

In some implementations, information associated with the optional transistor vertex OV11 may be included in the transistor vertex TV12 adjacent to (e.g., dependent on) the optional transistor vertex OV11. In other words, even if the final circuit graph 710 does not directly include the optional transistor vertex OV11, the final circuit graph 710 may include relevant information necessary to implement the optional transistor vertex OV11. For example, the optional transistor vertex OV11 and the transistor vertex TV12 may be grouped to form one group 712, and it may be implemented such that the group 712 includes the information associated with the optional transistor vertex OV11 and information associated with the transistor vertex TV12.

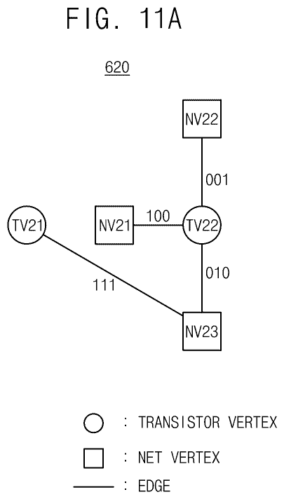

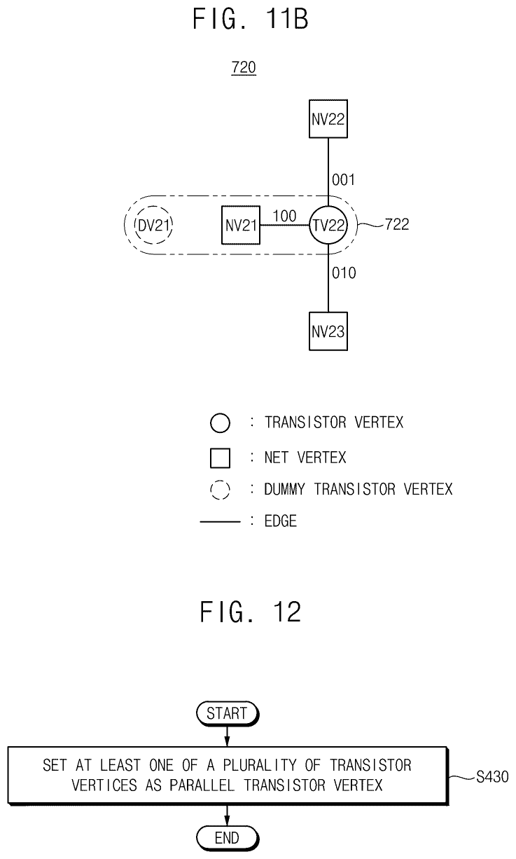

FIG. 10 is a flowchart illustrating an example of generating a final circuit graph in FIG. 1. FIGS. 11A and 11B are diagrams for describing an example of an operation of FIG. 10.

Referring to FIGS. 1 and 10, when generating the final circuit graph (operation S400), at least one of the plurality of transistor vertices may be set as a dummy transistor vertex (operation S420). For example, when a gate electrode, a source electrode and a drain electrode of a specific transistor are connected to the same node, e.g., when the specific transistor is a dummy transistor, a circuit graph including the specific transistor may be simplified by converting a transistor vertex corresponding to the specific transistor into a dummy transistor vertex.

Referring to FIGS. 11A and 11B, an example of a second circuit graph 620 obtained based on a netlist of a specific semiconductor circuit (or at least a part thereof) different from the netlist 210 of the semiconductor circuit of FIG. 5A is illustrated, and an example of a final circuit graph 720 obtained based on the second circuit graph 620 is illustrated.

The second circuit graph 620 of FIG. 11A may include transistor vertices TV21 and TV22, net vertices NV21, NV22 and NV23, and edges connected thereto. A structure of the second circuit graph 620 of FIG. 11A may be substantially the same as the structure of the circuit graph 611a on the right side of FIG. 9A, connections of the transistor vertices TV21 and TV22 and the net vertices NV21, NV22 and NV23 in FIG. 11A may be substantially the same as the connections of the transistor vertices TV11 and TV12 and the net vertices NV13, NV14 and NV15 on the right side of FIG. 9A, and thus descriptions repeated with or overlapping with the descriptions of FIG. 9A will be omitted in the interest of brevity. For example, in FIG. 11A, a gate electrode, a source electrode and a drain electrode of a transistor corresponding to the transistor vertex TV21 may be connected to the same net vertex NV23, and the transistor corresponding to the transistor vertex TV21 may be implemented as a dummy transistor.

Therefore, when operation S420 in FIG. 10 is performed on the second circuit graph 620, the transistor vertex TV21 may be set as a dummy transistor vertex DV21, the edges related to the transistor vertex TV21 may be omitted, and the final circuit graph 720 may be obtained as illustrated in FIG. 11B.

In some implementations, the dummy transistor vertex DV21 may be omitted from the final circuit graph 720. In other words, the final circuit graph 720 may not directly include the dummy transistor vertex DV21. For example, the final circuit graph 720 may have a 4V-3E structure.

In some implementations, information associated with the dummy transistor vertex DV21 may be included in the transistor vertex TV22 adjacent to (e.g., dependent on) the dummy transistor vertex DV21. In other words, even if the final circuit graph 720 does not directly include the dummy transistor vertex DV21, the final circuit graph 720 may include relevant information necessary to implement the dummy transistor vertex DV21. For example, the dummy transistor vertex DV21 and the transistor vertex TV22 may be grouped to form one group 722, and it may be implemented such that the group 722 includes the information associated with the dummy transistor vertex DV21 and information associated with the transistor vertex TV22.

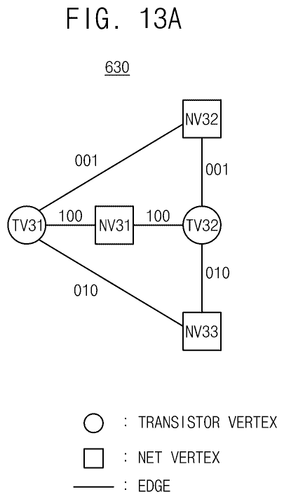

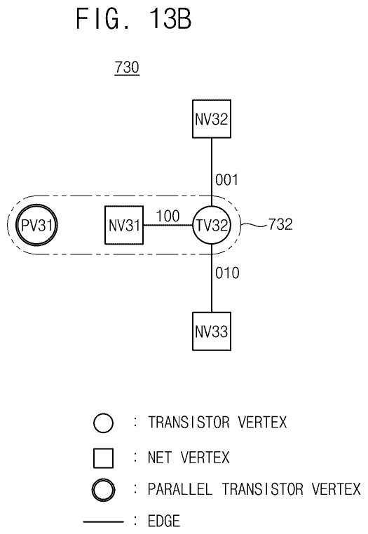

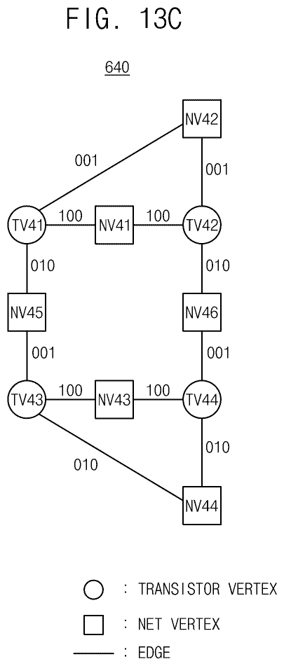

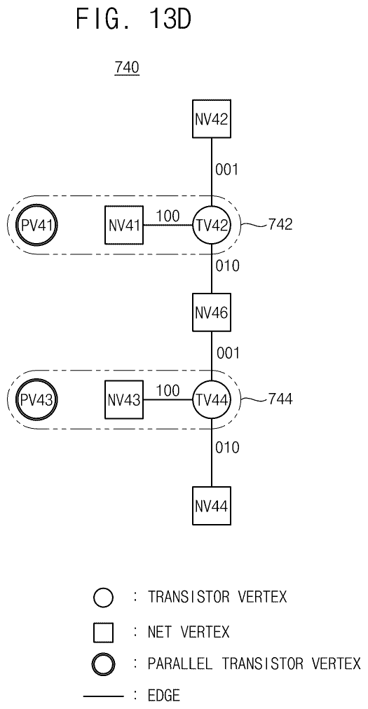

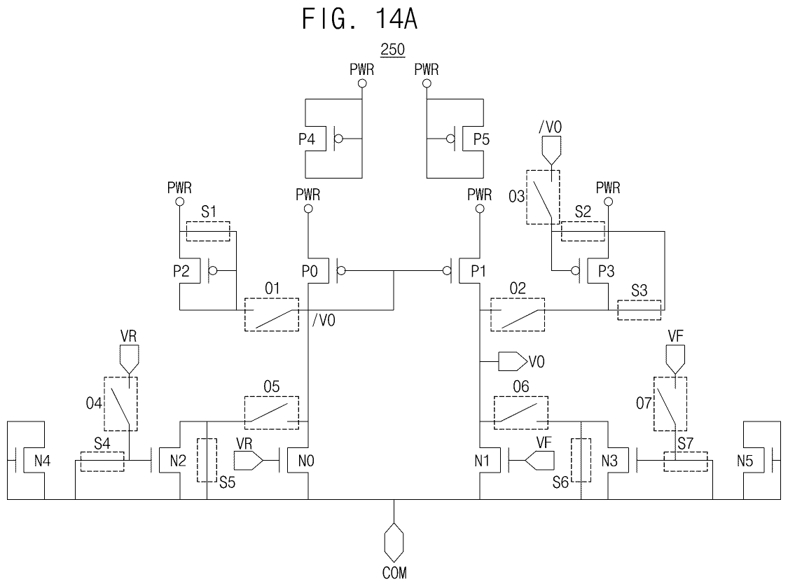

FIG. 12 is a flowchart illustrating an example of generating a final circuit graph in FIG. 1. FIGS. 13A, 13B, 13C, and 13D are diagrams for describing an example of an operation of FIG. 12.

Referring to FIGS. 1 and 12, when generating the final circuit graph (operation S400), at least one of the plurality of transistor vertices may be set as a parallel transistor vertex (operation S430). For example, when a connections of a specific transistor (e.g., connections between gate, source and drain electrodes of the specific transistor and specific nodes) is identical or corresponds to that of another transistor, e.g., when the specific transistor is connected in parallel with the another transistor, a circuit graph including the specific transistor may be simplified by converting a transistor vertex corresponding to the specific transistor into a parallel transistor vertex.

Referring to FIGS. 13A and 13B, an example of a second circuit graph 630 obtained based on a netlist of a specific semiconductor circuit (or at least a part thereof) different from the netlist 210 of the semiconductor circuit of FIG. 5A is illustrated, and an example of a final circuit graph 730 obtained based on the second circuit graph 630 is illustrated.

The second circuit graph 630 of FIG. 13A may include transistor vertices TV31 and TV32, net vertices NV31, NV32 and NV33, and edges connected thereto. A structure of the second circuit graph 630 of FIG. 13A may be substantially the same as the structure of the circuit graph 611b on the right side of FIG. 9B, connections of the transistor vertices TV31 and TV32 and the net vertices NV31, NV32 and NV33 in FIG. 13A may be substantially the same as the connections of the transistor vertices TV11 and TV12 and the net vertices NV13, NV14 and NV15 on the right side of FIG. 9B, and thus descriptions repeated with or overlapping with the descriptions of FIG. 9B will be omitted in the interest of brevity. For example, in FIG. 13A, connections of gate, source and drain electrodes of a transistor corresponding to the transistor vertex TV31 and connections of gate, source and drain electrodes of a transistor corresponding to the transistor vertex TV32 may be identical to each other, and the transistor corresponding to the transistor vertex TV31 may be implemented as a parallel transistor to the transistor corresponding to the transistor vertex TV32.

Therefore, when operation S430 in FIG. 12 is performed on the second circuit graph 630, the transistor vertex TV31 may be set as a parallel transistor vertex PV31 to the transistor vertex TV32, the edges related to the transistor vertex TV31 may be omitted, and the final circuit graph 730 may be obtained as illustrated in FIG. 13B.

In some implementations, the parallel transistor vertex PV31 may be omitted from the final circuit graph 730. In other words, the final circuit graph 730 may not directly include the parallel transistor vertex PV31. For example, the final circuit graph 730 may have a 4V-3E structure.

In some implementations, information associated with the parallel transistor vertex PV31 may be included in the adjacent transistor vertex TV32. In other words, the final circuit graph 730 may include relevant information necessary to implement the parallel transistor vertex PV31. For example, the parallel transistor vertex PV31 and the transistor vertex TV32 may be grouped to form one group 732, and it may be implemented such that the group 732 includes the information associated with the parallel transistor vertex PV31 and information associated with the transistor vertex TV32.

Referring to FIGS. 13C and 13D, an example of a second circuit graph 640 obtained based on a netlist of a specific semiconductor circuit (or at least a part thereof) different from the netlist 210 of the semiconductor circuit of FIG. 5A is illustrated, and an example of a final circuit graph 740 obtained based on the second circuit graph 640 is illustrated.

The second circuit graph 640 of FIG. 13C may include transistor vertices TV41, TV42, TV43 and TV44, net vertices NV41, NV42, NV43, NV44, NV45 and NV46, and edges connected thereto. With respect to the transistor vertices TV41 and TV42 and the edges connected thereto, it may be navigated from one net vertex (e.g., NV42) through different transistor vertices TV41 and TV42 to another net vertex (e.g., NV41). In addition, with respect to the transistor vertices TV43 and TV44 and the edges connected thereto, it may be navigated from one net vertex (e.g., NV44) through different transistor vertices TV43 and TV44 to another net vertex (e.g., NV43). In other words, in FIG. 13C, a connection of the transistor vertex TV41 and a connection of the transistor vertex TV42 may correspond to each other, and a transistor corresponding to the transistor vertex TV41 may be implemented as a parallel transistor to a transistor corresponding to the transistor vertex TV42. In addition, a connection of the transistor vertex TV43 and a connection of the transistor vertex TV44 may correspond to each other, and a transistor corresponding to the transistor vertex TV43 may be implemented as a parallel transistor to a transistor corresponding to the transistor vertex TV44. Further, a connection of the net vertex NV45 and a connection of the net vertex NV46 may correspond to each other, and a net corresponding to the net vertex NV45 may be implemented as a parallel net to a net corresponding to the net vertex NV46.

Therefore, when operation S430 in FIG. 12 is performed on the second circuit graph 640, the transistor vertex TV41 may be set as a parallel transistor vertex PV41, the transistor vertex TV43 may be set as a parallel transistor vertex PV43, the parallel net vertex NV45 and the edges related to the transistor vertices TV41 and TV43 may be omitted, and the final circuit graph 740 may be obtained as illustrated in FIG. 13D.

In some implementations, the parallel transistor vertices PV41 and PV43 and the parallel net vertex NV45 may be omitted from the final circuit graph 740. In other words, the final circuit graph 740 may not directly include the parallel transistor vertices PV41 and PV43 and the parallel net vertex NV45. For example, the final circuit graph 740 may have a 7V-6E structure.

In some implementations, information associated with the parallel transistor vertices PV41 and PV43 may be included in the adjacent transistor vertices TV42 and TV44. In other words, the final circuit graph 740 may include relevant information necessary to implement the parallel transistor vertices PV41 and PV43. For example, the parallel transistor vertex PV41 and the transistor vertex TV42 may be grouped to form one group 742, and it may be implemented such that the group 742 includes the information associated with the parallel transistor vertices PV41 and information associated with the transistor vertex TV42. For example, the parallel transistor vertex PV43 and the transistor vertex TV44 may be grouped to form one group 744, and it may be implemented such that the group 744 includes the information associated with the parallel transistor vertices PV43 and information associated with the transistor vertex TV44.

Although FIG. 13A illustrates that two transistors corresponding to the transistor vertices TV31 and TV32 are connected in parallel, and although FIG. 13C illustrates that two transistors corresponding to the transistor vertices TV41 and TV42 are connected in parallel and two transistors corresponding to the transistor vertices TV43 and TV44 are connected in parallel, implementations are not limited thereto, and implementations be applied or employed when three or more transistors are connected in parallel. Although FIG. 13A illustrates that the circuit graph includes one group including transistors connected in parallel, and although FIG. 13C illustrates that the circuit graph includes two groups each of which includes transistors connected in parallel, implementations are not limited thereto, and implementations be applied or employed when the circuit graph includes three or more groups each of which includes transistors connected in parallel.

When operation S400 is performed, an example of performing operation S410 in FIG. 8, an example of performing operation S420 in FIG. 10, and an example of performing operation S430 in FIG. 12 are illustrated. However, implementations are not limited thereto. For example, operation S400 may be performed by combining two or more of operations S410, S420 and S430.

FIGS. 14A, 14B, 14C, and 14D are diagrams for describing an example of a method of analyzing a semiconductor circuit.

Referring to FIGS. 1 and 14A, in operation S100, a netlist 250 of a differential amplifier circuit may be received. For example, FIG. 14A illustrates an example of a differential amplifier circuit having a derivation structure in which dummy transistors and optional transistors are added to a differential amplifier circuit having a basic structure. For example, the dummy transistors and the optional transistors may be added for various purposes.

The netlist 250 of the differential amplifier circuit having the derivation structure may include p-type metal oxide semiconductor (PMOS) transistors P0, P1, P2, P3, P4 and P5, NMOS transistors N0, N1, N2, N3, N4 and N5, and optional instances O1, O2, O3, O4, O5, O6, O7, S1, S2, S3, S4, S5, S6 and S7. For example, the optional instances O1, O2, O3, O4, O5, O6 and O7 may be implemented in the open state, and the optional instances S1, S2, S3, S4, S5, S6 and S7 may be implemented in the short state. The power supply voltage PWR, the common voltage COM, the reference voltage VR and the feedback voltage VF may be provided as illustrated, and an output voltage VO may be generated as illustrated. A voltage/VO may be an inverted voltage of the output voltage VO.

Referring to FIGS. 1 and 14B, in operation S200, a first circuit graph 550 may be generated based on the netlist 250. For example, the first circuit graph 550 may be generated based on the operations described with reference to FIGS. 4, 5A and 5B.

The first circuit graph 550 may include transistor vertices corresponding to the transistors P0, P1, P2, P3, P4, P5, N0, N1, N2, N3, N4 and N5, net vertices corresponding to nodes V1, V2, V3, V4, V5, V6 and V7 connected to electrodes of the transistors and/or corresponding to the voltages PWR, COM, VO,/VO, VR and VF provided to and generated from the electrodes of the transistors, optional instance vertices corresponding to the optional instances O1, O2, O3, O4, O5, O6, O7, S1, S2, S3, S4, S5, S6 and S7, and edges connected to the above-described vertices.

Referring to FIGS. 1 and 14C, in operation S300, a second circuit graph 650 may be generated based on the first circuit graph 550. For example, the second circuit graph 650 may be generated based on the operations described with reference to FIGS. 6 and 7.

The second circuit graph 650 may include transistor vertices corresponding to the transistors P0, P1, P2, P3, P4, P5, N0, N1, N2, N3, N4 and N5, net vertices corresponding to nodes V1, V2, V3, V4, V5, V6 and V7 connected to electrodes of the transistors and/or corresponding to the voltages PWR, COM, VO,/VO, VR and VF provided to and generated from the electrodes of the transistors, and edges and optional edges connected to the above-described vertices. As compared with the first circuit graph 550, the second circuit graph 650 may be simplified by converting the optional instance vertices and the edges directly connected thereto into the optional edges.

Referring to FIGS. 1 and 14D, in operation S400, a final circuit graph 750 may be generated based on the second circuit graph 650. For example, the final circuit graph 750 may be generated based on the operations described with reference to FIGS. 8, 9A, 9B, 9C, 10, 11A, 11B, 12, 13A, 13B, 13C and 13D.

The final circuit graph 750 may include transistor vertices corresponding to the transistors P0, P1, N0 and N1, net vertices the voltages PWR, COM, VO,/VO, VR and VF provided to and generated from the electrodes of the transistors, and edges connected to the above-described vertices. As compared with the second circuit graph 650, the final circuit graph 750 may be simplified by setting transistor vertices corresponding to the transistors P2, P3, N2 and N3 as optional transistor vertices and by omitting the optional transistor vertices, by setting transistor vertices corresponding to the transistors P4, P5, N4 and N5 as dummy transistor vertices and by omitting the dummy transistor vertices, by omitting net vertices corresponding to the nodes V1, V2, V3, V4, V5, V6 and V7, and by omitting edges related to the omitted vertices.

The final circuit graph 750 may include four groups 752, 754, 756 and 758. It may be implemented such that the group 752 includes information associated with the transistor vertex corresponding to the transistor P0, the optional transistor vertex corresponding to the transistor P2, and the dummy transistor vertex corresponding to the transistor P4. It may be implemented such that the group 754 includes information associated with the transistor vertex corresponding to the transistor P1, the optional transistor vertex corresponding to the transistor P3, and the dummy transistor vertex corresponding to the transistor P5. It may be implemented such that the group 756 includes information associated with the transistor vertex corresponding to the transistor N0, the optional transistor vertex corresponding to the transistor N2, and the dummy transistor vertex corresponding to the transistor N4. It may be implemented such that the group 758 includes information associated with the transistor vertex corresponding to the transistor N1, the optional transistor vertex corresponding to the transistor N3, and the dummy transistor vertex corresponding to the transistor N5.

FIG. 15 is a flowchart illustrating an example of a method of analyzing a semiconductor circuit. The descriptions repeated with or overlapping with the descriptions of FIG. 1 will be omitted in the interest of brevity.

Referring to FIG. 15, in a method of analyzing a semiconductor circuit, operations S100, S200, S300 and S400 may be substantially the same as those described with reference to FIG. 1.

A target semiconductor circuit may be obtained by searching for a database based on the final circuit graph (operation S500). The target semiconductor circuit may be matched with the semiconductor circuit corresponding to the netlist received in operation S100. For example, as described with reference to FIG. 2, the database may be disposed or located outside the analysis system that performs the method of analyzing the semiconductor circuit, and the plurality of semiconductor circuits CKT and the circuit information CKT_INF may be stored in the database. For example, a semiconductor circuit having a circuit graph matching the final circuit graph may be obtained as the target semiconductor circuit. In some implementations, the target semiconductor circuit and target circuit information associated with the target semiconductor circuit may be obtained together.

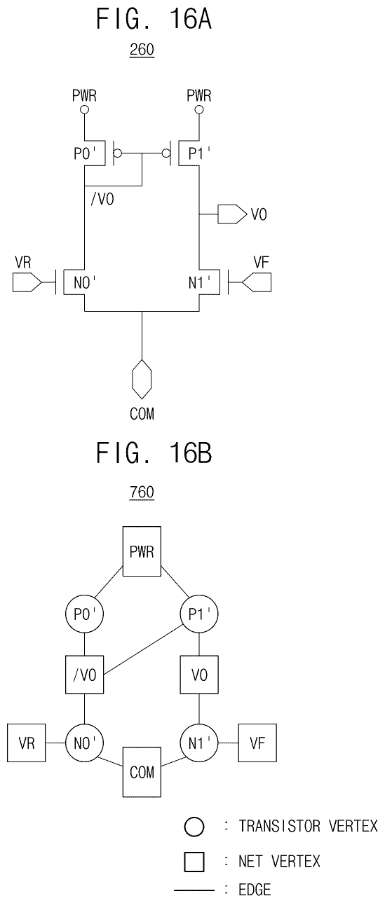

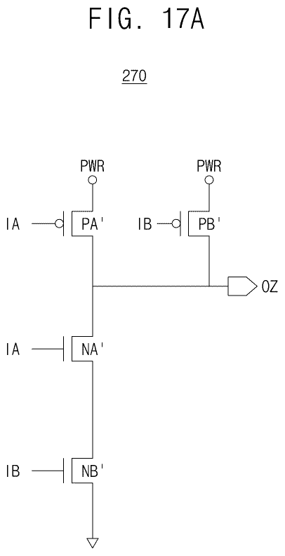

FIGS. 16A, 16B, 17A, 17B, 18A, 18B, and 18C are diagrams for describing an example of a method of analyzing a semiconductor circuit.

Referring to FIGS. 16A and 16B, an example of a netlist 260 of a differential amplifier circuit is illustrated, and an example of a circuit graph 760 obtained based on the netlist 260 is illustrated. For example, FIG. 16A illustrates a differential amplifier circuit having a basic structure.

The netlist 260 of the differential amplifier circuit having the basic structure may include PMOS transistors P0′ and P1′ and NMOS transistors N0′ and N1′, and voltages PWR, COM, VO,/VO, VR and VF may be provided and generated as illustrated.

The circuit graph 760 may include transistor vertices corresponding to the transistors P0′, P1′, N0′ and N1′, net vertices corresponding to the voltages PWR, COM, VO,/VO, VR and VF provided to and generated from electrodes of the transistors, and edges connecting the above-described vertices.

In some implementations, as described with reference to FIGS. 14A, 14B, 14C and 14D, the final circuit graph 750 that is obtained by performing the method of analyzing the semiconductor circuit on the netlist 250 of the differential amplifier circuit having the derivation structure may be substantially identical to the circuit graph 760 of the netlist 260 of the differential amplifier circuit having the basic structure.

In some implementations, the netlist 260 of the differential amplifier circuit having the basic structure and the circuit graph 760 corresponding thereto may be stored in the database 1400 as one of the plurality of semiconductor circuits CKT, and the method of analyzing the semiconductor circuit may be performed on the netlist 250 of the differential amplifier circuit having the derivation structure. In this example, since the final circuit graph 750 obtained by performing the method of analyzing the semiconductor circuit on the netlist 250 of the differential amplifier circuit having the derivation structure is substantially identical to the circuit graph 760 of the netlist 260 of the differential amplifier circuit having the basic structure, the circuit graph 760 matching the final circuit graph 750 and the netlist 260 of the differential amplifier circuit having the basic structure corresponding to the circuit graph 760 may be obtained when the database 1400 is searched for based on the final circuit graph 750.

If the database 1400 is searched for without simplifying the circuit graph based on a conventional scheme, the netlist 250 of the differential amplifier circuit having the derivation structure and the netlist 260 of the differential amplifier circuit having the basic structure may not be matched with each other. In contrast, when the database 1400 is searched for using the final circuit graph 750 whose structure is simplified, the netlist 250 of the differential amplifier circuit having the derivation structure and the netlist 260 of the differential amplifier circuit having the basic structure may be matched with each other. Accordingly, relatively faster search may be performed using relatively fewer resources (e.g., memory).

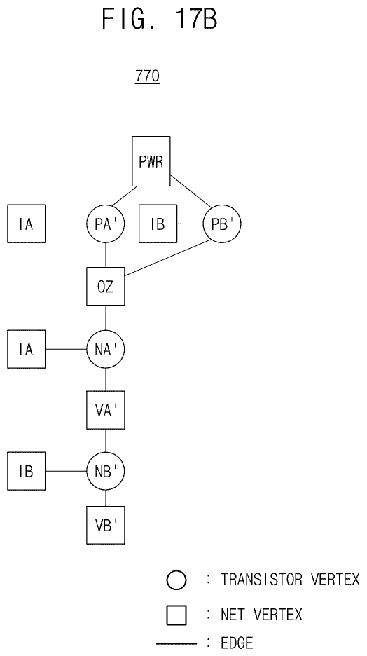

Referring to FIGS. 17A and 17B, an example of a netlist 270 of a NAND gate is illustrated, and an example of a circuit graph 770 obtained based on the netlist 270 is illustrated. For example, FIG. 17A illustrates a NAND gate having a basic structure.

The netlist 270 of the NAND gate having the basic structure may include PMOS transistors PA′ and PB′ and NMOS transistors NA′ and NB′, a power supply voltage PWR and input signals IA, IB may be provided as illustrated, and an output signal OZ may be generated as illustrated.

The circuit graph 770 may include transistor vertices corresponding to the transistors PA′, PB′, NA′ and NB′, net vertices corresponding to nodes VA′ and VB′ connected to electrodes of the transistors and/or corresponding to the voltage and signals PWR, IA, IB and OZ provided to and generated from the electrodes of the transistors, and edges connected to the above-described vertices.

In some implementations, the netlist 270 of the NAND gate having the basic structure and the circuit graph 770 corresponding thereto may be stored in the database 1400 as one of the plurality of semiconductor circuits CKT.

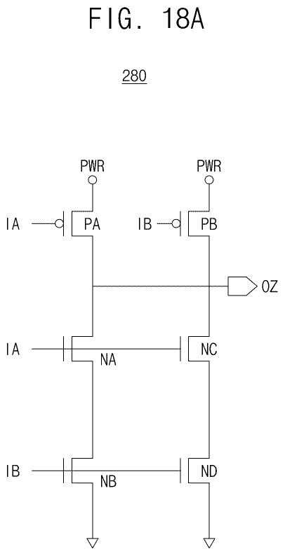

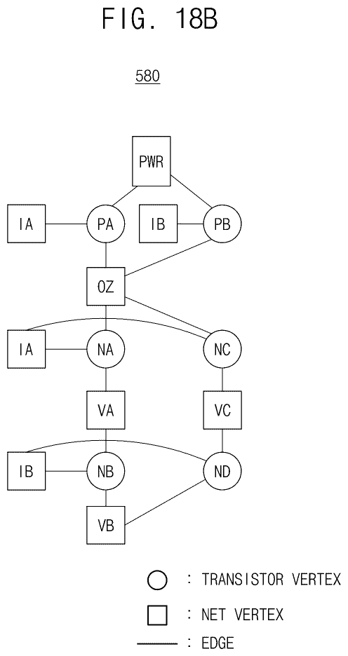

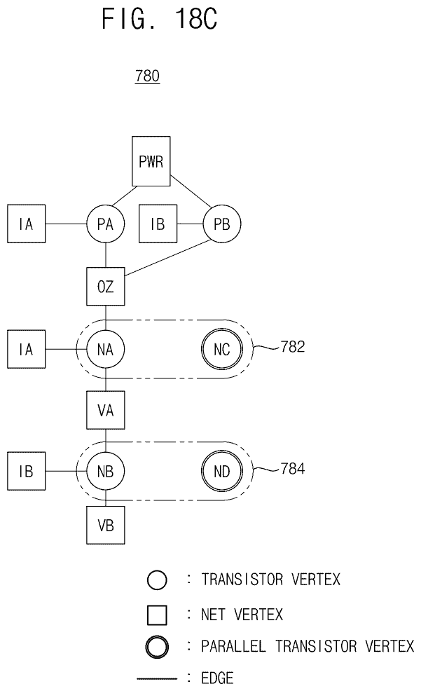

Referring to FIGS. 18A, 18B and 18C, an example of a netlist 280 of a NAND gate is illustrated, and an example of a first circuit graph 580 and an example of a final circuit graph 780 that are obtained by performing the method of analyzing the semiconductor circuit on the netlist 280 are illustrated. For example, FIG. 18A illustrates a NAND gate having a derivation structure in which parallel transistors are added to the NAND gate having the basic structure. For example, the parallel transistors may be added for improving layout efficiency.

The netlist 280 of the NAND gate having the derivation structure may include PMOS transistors PA and PB and NMOS transistors NA, NB, NC and ND, a power supply voltage PWR and input signals IA and IB may be provided as illustrated, and an output signal OZ may be generated as illustrated.

The first circuit graph 580 may include transistor vertices corresponding to the transistors PA, PB, NA, NB, NC and ND, net vertices corresponding to nodes VA, VB and VC connected to electrodes of the transistors and/or corresponding to the voltage and signals PWR, IA, IB and OZ provided to and generated from the electrodes of the transistors, and edges connected to the above-described vertices.

The final circuit graph 780 may include transistor vertices corresponding to the transistors PA, PB, NA and NB, net vertices corresponding to the voltage and signals PWR, IA, IB and OZ provided to and generated from the electrodes of the transistors, and edges connected to the above-described vertices. As compared with the first circuit graph 580, the final circuit graph 780 may be simplified by setting transistor vertices corresponding to the transistors NC and ND as parallel transistor vertices and by omitting the parallel transistor vertices, by omitting net vertex corresponding to the node VC, and by omitting edges related to the omitted vertices.

In some implementations, the final circuit graph 780 that is obtained by performing the method of analyzing the semiconductor circuit on the netlist 280 of the NAND gate having the derivation structure may be substantially identical to the circuit graph 770 of the netlist 270 of the NAND gate having the basic structure. Therefore, when the database 1400 is searched for based on the final circuit graph 780, the circuit graph 770 matching the final circuit graph 780 and the netlist 270 of NAND gates having the basic structure corresponding to the circuit graph 770 may be obtained.

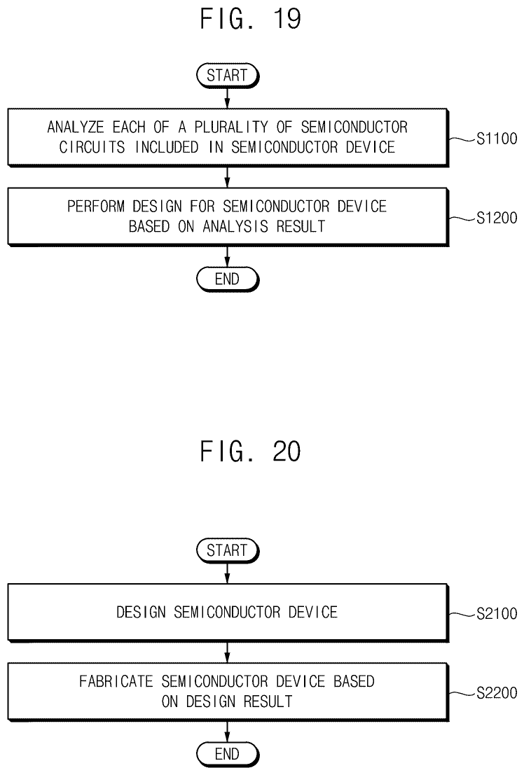

FIG. 19 is a flowchart illustrating an example of a method of designing a semiconductor device.

Referring to FIG. 19, in a method of designing a semiconductor device, each of a plurality of semiconductor circuits included in the semiconductor device is analyzed (operation S1100), and a design for the semiconductor device is performed based on an analysis result, e.g., a result of analyzing each of the plurality of semiconductor circuits (operation S1200). Operation S1100 may be performed based on the method of analyzing the semiconductor circuit, which is described with reference to FIGS. 1 through 18C.

In some implementations, operations S1100 and S1200 may be performed during an RTL design of the semiconductor device. However, implementations are not limited thereto.

In some implementations, a target semiconductor circuit that is obtained as the analysis result may be used to perform circuit configuration, layout, etc. for the semiconductor device, and/or verification, etc. may be performed using information associated with or related to the target semiconductor circuit. However, implementations are not limited thereto.

Typically, a design process of a semiconductor device may include a behavior level design (or behavior level design process) corresponding to a functional design of the entire semiconductor device, an RTL design (or RTL design process) of the semiconductor device, a gate level design (or gate level design process) of the semiconductor device, and a layout level design (or layout level design process) of the semiconductor device.

The behavior level design may be referred to as an architecture design or a high level design (or high level design process). The high level design may represent that a semiconductor device to be designed or as a target device is depicted at an algorithm level and is described in terms of high-level computer language (e.g., C language).

Devices and/or circuits designed by the high level design process may be more concretely described by an RTL coding or simulation. In addition, codes generated by the RTL coding may be converted into a netlist, and the results may be combined with each other to realize the entire semiconductor device. The combined schematic circuit may be verified by a simulation tool. In some implementations, an adjusting operation may be further performed in consideration of a result of the verification.

The RTL may be used for representing a coding style used in hardware description languages for effectively ensuring that code models may be synthesized in a certain hardware platform such as an FPGA or an ASIC (e.g., code models may be converted into real logic functions). A plurality of hardware description languages may be used for generating RTL modules. For example, the plurality of hardware description languages may include System Verilog, Verilog, VHDL, or the like.

The gate level design may represent that a semiconductor device is depicted using basic logic gates, such as AND gates and OR gates, and is described by logical connections and timing information of the logic gates. For example, all signals may be discrete signals and may only have a logical value of zero, one, X and Z (or high-Z).

The layout level design may be referred to as a physical design (or physical design process). The layout level design may be performed to implement or realize a logically completed semiconductor device on a silicon substrate. For example, the layout level design may be performed based on the schematic circuit prepared in the high level design or the netlist corresponding thereto. The layout level design may include a routing operation of placing and connecting various standard cells that are provided from a cell library, based on a predetermined design rule.

A cell library for the layout level design may contain information on operation, speed, and power consumption of the standard cells. In some implementations, the cell library for representing a layout of a circuit having a specific gate level may be defined in a layout design tool. Here, the layout may be prepared to define or describe shapes and sizes of patterns constituting transistors and metal interconnection lines, which will be actually formed on a silicon substrate. For example, layout patterns (e.g., PMOS, NMOS, N-WELL, gate electrodes, and metal interconnection lines thereon) may be suitably disposed to actually form an inverter circuit on a silicon substrate. For this, at least one of inverters defined in the cell library may be selected.

In addition, the routing operation may be performed on selected and disposed standard cells. In detail, the routing operation may be performed on the selected and disposed standard cells to connect them to upper interconnection lines. By the routing operation, the standard cells may be electrically connected to each other to meet a design.

The method of analyzing the semiconductor circuit may be used during the above-described various design processes.

FIG. 20 is a flowchart illustrating an example of a method of manufacturing a semiconductor device.

Referring to FIG. 20, in a method of manufacturing a semiconductor device, the semiconductor device is designed (operation S2100), and the semiconductor device is fabricated based on a design result, e.g., a result of designing the semiconductor device (operation S2200). Operation S2100 may be performed based on the method of designing the semiconductor device, which is described with reference to FIG. 19.

In operation S2200, the semiconductor device may be fabricated or manufactured by a mask, a wafer, a test, an assembly, packaging, and the like. For example, a corrected layout may be generated by performing optical proximity correction on a design layout, and a photo mask may be fabricated or manufactured based on the corrected layout. For example, various types of exposure and etching processes may be repeatedly performed using the photo mask, and patterns corresponding to the layout design may be sequentially formed on a substrate through these processes. Thereafter, the semiconductor device may be obtained in the form of a semiconductor chip through various additional processes.

While this specification contains many specific implementation details, these should not be construed as limitations on the scope of any invention or on the scope of what may be claimed, but rather as descriptions of features that may be specific to particular implementations of particular inventions. Certain features that are described in this specification in the context of separate implementations can also be implemented in combination in a single implementation. Conversely, various features that are described in the context of a single implementation can also be implemented in multiple implementations separately or in any suitable subcombination. Moreover, although features may be described above as acting in certain combinations, one or more features from a combination can in some cases be excised from the combination, and the combination may be directed to a subcombination or variation of a subcombination.

As will be appreciated by those skilled in the art, the present disclosure may be implemented as a system, method, computer program product, and/or a computer program product implemented in one or more computer readable medium(s) having computer readable program code implemented thereon. The computer readable program code may be provided to a processor of a general purpose computer, special purpose computer, or other programmable data processing apparatus. The computer readable medium may be a computer readable signal medium or a computer readable storage medium. The computer readable storage medium may be any tangible medium that can contain or store a program for use by or in connection with an instruction execution system, apparatus, or device. For example, the computer readable medium may be a non-transitory computer readable medium.

The implementations may be applied to design and manufacture various electronic devices and systems that include the semiconductor circuits and/or devices. For example, the implementations may be applied to systems such as a personal computer (PC), a server computer, a data center, a workstation, a mobile phone, a smart phone, a tablet computer, a laptop computer, a personal digital assistant (PDA), a portable multimedia player (PMP), a digital camera, a portable game console, a music player, a camcorder, a video player, a navigation device, a wearable device, an internet of things (IoT) device, an internet of everything (IoE) device, an e-book reader, a virtual reality (VR) device, an augmented reality (AR) device, a robotic device, a drone, an automotive, etc.

The foregoing is illustrative of implementations and is not to be construed as limiting thereof. Although some implementations have been described, those skilled in the art will readily appreciate that many modifications are possible in the implementations without materially departing from the novel teachings and advantages of the implementations. Accordingly, all such modifications are intended to be included within the scope of the implementations as defined in the claims. Therefore, it is to be understood that the foregoing is illustrative of various implementations and is not to be construed as limited to the specific implementations disclosed, and that modifications to the disclosed implementations, as well as other implementations, are intended to be included within the scope of the appended claims.

What is claimed is:

1. A method of analyzing a semiconductor circuit, the method being performed by at least one processor executing program code, the program code being stored in a non-transitory computer readable medium, the method comprising:
receiving a netlist of the semiconductor circuit, the semiconductor circuit including a plurality of transistors and a plurality of optional instances;
generating a first circuit graph based on the netlist of the semiconductor circuit, the first circuit graph including a plurality of vertices and a plurality of edges;
generating a second circuit graph based on the first circuit graph, the second circuit graph including the plurality of optional instances that are simplified from the first circuit graph; and
generating a final circuit graph based on the second circuit graph, the final circuit graph including at least one transistor of the plurality of transistors that is simplified from the second circuit graph.

2. The method of claim 1, wherein generating the first circuit graph includes:
generating a plurality of transistor vertices based on the plurality of transistors;
generating a plurality of net vertices based on a plurality of electrodes of the plurality of transistors;
generating a plurality of optional instance vertices based on the plurality of optional instances; and
generating the plurality of edges configured to connect the plurality of transistor vertices, the plurality of net vertices, and the plurality of optional instance vertices with each other.

3. The method of claim 2, wherein generating the second circuit graph includes:
generating a plurality of optional edges based on the plurality of optional instance vertices and at least one edge of the plurality of edges.

4. The method of claim 3, wherein generating the final circuit graph includes:
setting at least one vertex of the plurality of transistor vertices as a dummy transistor vertex.

5. The method of claim 4, wherein the plurality of transistor vertices includes a first transistor vertex,
wherein the first transistor vertex is configured to, based on a gate electrode, a source electrode, and a drain electrode of the first transistor vertex being connected to a same net vertex, be set as the dummy transistor vertex.

6. The method of claim 5, wherein the final circuit graph is free of the dummy transistor vertex.

7. The method of claim 6, wherein a transistor vertex adjacent to the dummy transistor vertex includes information associated with the dummy transistor vertex.

8. The method of claim 3, wherein generating the final circuit graph includes:
setting at least one vertex of the plurality of transistor vertices as an optional transistor vertex.

9. The method of claim 8, wherein the plurality of transistor vertices includes a second transistor vertex,
wherein the second transistor vertex is configured to, based on a connection of the second transistor vertex being changed according to the plurality of optional edges, be set as the optional transistor vertex.

10. The method of claim 9, wherein the final circuit graph is free of the optional transistor vertex.

11. The method of claim 10, wherein a transistor vertex adjacent to the optional transistor vertex includes information associated with the optional transistor vertex.

12. The method of claim 3, wherein generating the final circuit graph includes:
setting at least one vertex of the plurality of transistor vertices as a parallel transistor vertex.

13. The method of claim 12, wherein the plurality of transistor vertices includes a third transistor vertex and a fourth transistor vertex, and
wherein the third transistor vertex is configured to, based on a correspondence between a connection of the third transistor vertex and a connection of the fourth transistor vertex, be set as the parallel transistor vertex.

14. The method of claim 13, wherein the final circuit graph is free of the parallel transistor vertex.

15. The method of claim 14, wherein a transistor vertex adjacent to the parallel transistor vertex includes information associated with the parallel transistor vertex.

16. The method of claim 1, comprising:
obtaining a target semiconductor circuit based on searching a database, the database being based on the final circuit graph, the target semiconductor circuit being matched with the semiconductor circuit.

17. The method of claim 1, wherein each optional instance of the plurality of optional instances is a metal optional instance.

18. An analysis system comprising:
at least one processor; and
a non-transitory computer readable medium storing program code that, when executed by the at least one processor, causes the analysis system to perform operations comprising:
receiving a netlist of a semiconductor circuit;
generating a first circuit graph based on the netlist of the semiconductor circuit, the first circuit graph including a plurality of vertices and a plurality of edges;
generating a second circuit graph based on the first circuit graph, the second circuit graph including a plurality of optional instances that are simplified from the first circuit graph; and
generating a final circuit graph based on the second circuit graph, the final circuit graph including at least one transistor of a plurality of transistors that is simplified from the second circuit graph.

19. The analysis system of claim 18, wherein the operations comprises:
obtaining a target semiconductor circuit based on searching an external database, the external database being based on the final circuit graph, the target semiconductor circuit being matched with the semiconductor circuit.

20. A method of designing a semiconductor device, the semiconductor device including a plurality of semiconductor circuits, and the method comprising:
analyzing each semiconductor circuit of the plurality of semiconductor circuits using at least one processor executing program code that is stored in a non-transitory computer readable medium; and
designing the semiconductor device based on a result of analyzing each semiconductor circuit of the plurality of semiconductor circuits,
wherein each semiconductor circuit of the plurality of semiconductor circuits includes a plurality of transistors and a plurality of optional instances, and
wherein analyzing each semiconductor circuit of the plurality of semiconductor circuits includes:
receiving a netlist of a first semiconductor circuit among the plurality of semiconductor circuits;
generating a first circuit graph based on the netlist of the first semiconductor circuit, the first circuit graph including a plurality of vertices and a plurality of edges;
generating a second circuit graph based on the first circuit graph, the second circuit graph including the plurality of optional instances that are simplified from the first circuit graph; and
generating a final circuit graph based on the second circuit graph, the final circuit graph including at least one transistor of the plurality of transistors that is simplified from the second circuit graph.
